(19) United States
(12) Patent Application Publication
(10) Pub. No.: US 2006/0187350 A1
(43) Pub. Date: Aug. 24, 2006

(54) Image display apparatus having automatic adjusting function and method thereof

(75) Inventors: Kil-young Shin, Suwon-si (KR); Kwang-ho Lee, Anyang-si (KR); Jong-hoon Lee, Suwon-si (KR); Jin-hun Kim, Seoul (KR)

Correspondence Address: SUGHRUE MION, PLLC, 2100 PENNSYLVANIA AVENUE, N.W., SUITE 800, WASHINGTON, DC, 20037, US

(73) Assignee: SAMSUNG ELECTRONICS CO., LTD.

(21) Appl. No.: 11/344,066

(22) Filed: Feb. 1, 2006

(30) Foreign Application Priority Data
Feb. 14, 2005 (KR) 2005-0012065

(51) Int. Cl. H03L 7/00; H03M 1/12

(52) U.S. Cl. 348/542; 348/540; 348/572

(57) ABSTRACT

An image display apparatus having an automatic adjusting function and a method thereof The image display apparatus includes an analog-to-digital (AD) converter for converting analog image signals received from a host computer into digital image data, a phase-locked loop (PLL) circuit for providing the AD converter with synchronization signals needed for converting the analog image signals into the digital image data, and a scaler for calculating a Horizontal Active Width from the digital image data, comparing the calculated Horizontal Active Width with the default Horizontal Active Width corresponding to the default mode, and transferring compensation data to the PLL circuit to compensate for the difference in the Horizontal Active Width. Accordingly, the image display apparatus is automatically adjusted according to the input image mode, thereby displaying high quality images on a screen.

### CROSS-REFERENCE TO RELATED APPLICATION

This application claims benefit under 35 U.S.C. § 119 from Korean Patent Application No. 2005-12065, filed Feb. 14, 2005, the entire contents of which are incorporated herein by reference.

### BACKGROUND OF THE INVENTION

1. Field of the Invention

The present invention relates to an image display apparatus having an automatic adjusting function and a method thereof. More specifically, the invention relates to an image display apparatus having an automatic adjusting function and a method thereof, in which horizontal and vertical positioning, and coarse and fine frequency tuning functions are automatically performed according to the image mode received from a host computer.

2. Description of the Related Art

Generally, an image display apparatus having functions of a television (TV) or a monitor performs signal processing on broadcast signals transmitted from broadcasting stations, image signals transmitted from video servers such as a digital versatile disc (DVD), and image signals transmitted from a host computer, and displays the processed signals on a screen. Here, images signals corresponding to various image modes such as Super Video Graphics Array (SVGA), Extended Graphics Array (XGA), Super XGA (SXGA), and the like are included in the image signals transmitted from the host computer, therefore an automatic adjusting function in accordance with the mode of the input image signals is needed in an image display apparatus.

FIG. 1 is a block diagram showing a configuration of a conventional image display apparatus.

Referring to FIG. 1, a conventional image display apparatus comprises an analog-to-digital (AD) converter 10, a scaler 12, a display panel 14, and a phase-locked loop (PLL) circuit 16.

The AD converter 10 samples analog image signals received from a host computer according to synchronization signals provided by the PLL circuit 16 described below, and converts the sampled signals into digital image data. Here, the PLL circuit 16 refers to a mode table supported by the image display apparatus, and provides synchronization signals to the AD converter 10. The AD converter 10 converts analog image signals into digital image data corresponding to the default mode according to the synchronization signals.

The scaler 12 receives digital image data from the AD converter 10, and calculates horizontal and vertical positions. The scaler 12 performs coarse and fine frequency tuning, and displays digital image data on a screen. Here, if errors occur in the data due to the diversity of the input image mode, the data corresponding to horizontal and vertical positioning, and coarse and fine frequency tuning of the digital image data, the scaler 12 feeds back compensation data to the PLL circuit 16 using registers (not shown) provided in the scaler itself, in order to compensate for the data corresponding to horizontal and vertical positioning, and coarse and fine frequency tuning. In this manner, an image display apparatus embodies the best displaying status. These operations are called automatic adjusting functions.

The PLL circuit 16 provides the AD converter 10 with synchronization signals needed for converting analog image signals into digital image data. In addition, according to the compensation data fed back from the scaler 12, the PLL circuit 16 provides the AD converter 10 with synchronization signals for obtaining data corresponding to accurate horizontal and vertical positioning, and coarse and fine frequency tuning.

The display panel 14 displays the digital image data scaled at the scaler 12 on a screen.

In this way, a conventional image display apparatus supports both monitor and TV functions, so that the scaler 12 calculates horizontal and vertical positions corresponding to the default mode, and automatically performs coarse and fine frequency tuning on the image signals received from a host computer, using the registers (not shown) that the scaler 12 has therein. The registers are hardware devices that are provided in the scaler 12 and are used to perform automatic adjusting functions.

However, as digital TV (DTV) markets prosper, DTV-dedicated scalers are being developed, the scalers having functions for accurately processing the broadcast signals transmitted from broadcasting stations or the image signals, such as a DVD signal, transmitted from video servers. However, those scalers frequently do not have registers that perform automatic adjusting functions according to the image mode received from a host computer. In addition, scalers developed in the past are TV-dedicated scalers, and thus do not have registers performing automatic adjusting functions. Therefore, image display apparatuses developed in the past cannot perform automatic adjusting functions, so that image quality problems arise.

### SUMMARY OF THE INVENTION

The present invention provides an image display apparatus having an automatic adjusting function and a method thereof, which does not require the hardware for performing automatic adjusting functions according to various image modes received from a host computer, but uses algorithms to display image signals of various modes received from a host computer on a screen.

According to an aspect of the invention, there is provided an image display apparatus, the apparatus comprising an AD converter for converting analog image signals received from a host computer into digital image data, a PLL circuit for providing the AD converter with synchronization signals needed for converting the analog image signals into the digital image data, and a scaler for calculating a Horizontal Active Width from the digital image data, comparing the calculated Horizontal Active Width with the default Horizontal Active Width corresponding to the default mode, and transferring compensation data to the PLL circuit to compensate for the difference in the Horizontal Active Width.

The PLL circuit adjusts the synchronization signals according to the compensation data, and provides the adjusted signals to the AD converter.

The scaler includes a detector for detecting the start point and the end point of the Horizontal Active Width, a calculator for calculating the Horizontal Active Width using the start point and the end point, comparing the Horizontal Active Width with the default Horizontal Active Width, and creating compensation data for compensating the Horizontal Active Width, and a coordinator for transferring the compensation data to the PLL circuit and controlling the PLL circuit so as to compensate the synchronization signals.

The detector determines a Capture Rectangle (CR) region including a certain pixel section of a horizontal “back porch” region that is a blank region not included in the Horizontal Active Width, compares pixel values with a certain threshold value, the pixel values starting from the pixel value of the first pixel in the CR region, and determines the first pixel having a pixel value larger than the threshold value as the start point.

In addition, the detector determines a CR region including a certain pixel section of a horizontal “front porch” region that is a blank region not included in the Horizontal Active Width, compares pixel values with a certain threshold value, the pixel values starting from the pixel value of the last pixel in the CR region, and detects the first pixel having a pixel value larger than the threshold value as the end point.

The calculator calculates the Horizontal Active Width using the formula:
Horizontal Active Width=default Horizontal Active Width+(start point−end point)

In addition, the calculator calculates compensation data for compensating the Horizontal Total Width, which comprises the Horizontal Active Width and the blank region, so as to have the same value as the default Horizontal Total Width that corresponds to a default mode, the blank region not being included in the Horizontal Active Width and comprising the horizontal back porch region and the horizontal front porch region.

According to another aspect of the invention, there is provided an automatic adjusting method for the image display apparatus comprising: providing synchronization signals needed to convert analog image signals received from a host computer into digital image data, converting the analog image signals into the digital image data according to the synchronization signals, calculating a Horizontal Active Width from the digital image data, and creating compensation data for compensating for the difference in the Horizontal Active Width after comparing the Horizontal Active Width with the default Horizontal Active Width corresponding to the default mode.

In addition, the automatic adjusting method for the image display apparatus further comprises compensating the synchronization signals according to the compensation data, converting the analog image signals into the digital image data according to the compensated synchronization signals, and displaying the digital image data on a screen after scaling.

Here, the calculating the Horizontal Active Width calculates the size of the Horizontal Active Width using the mathematical formula described below:
Horizontal Active Width=default Horizontal Active Width+(start point+end point)

In the above formula, when a certain threshold value is compared with the pixel values, the pixel values starting from the first pixel value in a CR region including a certain pixel section of a Horizontal Back Porch region, the start point is the first pixel having a larger pixel value than the threshold value, and, when a certain threshold value is compared with the pixel values, the pixel values starting from the last pixel value in the CR region including a certain pixel section of a Horizontal Front Porch region, the end point is the first pixel having a larger pixel value than the threshold value.

In addition, the creating compensation data preferably calculates compensation data for compensating the Horizontal Total Width, which comprises the Horizontal Active Width and the blank region, so as to have the same value as the default Horizontal Total Width that corresponds to a default mode, the blank region not being included in the Horizontal Active Width and comprising the horizontal back porch region and the horizontal front porch region.

### BRIEF DESCRIPTION OF THE DRAWINGS

The above and/or other aspects the present invention will be more apparent by describing certain exemplary embodiments of the present invention with reference to the accompanying drawings, in which:

FIG. 1 is a block diagram showing a configuration of a conventional image display apparatus;

FIG. 2 is a block diagram showing a configuration of an image display apparatus according to an exemplary embodiment of the invention;

FIG. 3 explains the operation of the scaler of an image display apparatus according to an exemplary embodiment of the invention;

FIGS. 4A and 4B explain a method of detecting a start point and an end point from a crosshatch pattern for an image display apparatus according to an exemplary embodiment of the invention;

FIGS. 5A and 5B explain a method of detecting a start point and an end point from a “1 dot on/off” pattern for an image display apparatus according to an exemplary embodiment of the invention; and

FIG. 6 is a flowchart explaining the operation of an image display apparatus according to an exemplary embodiment of the invention.

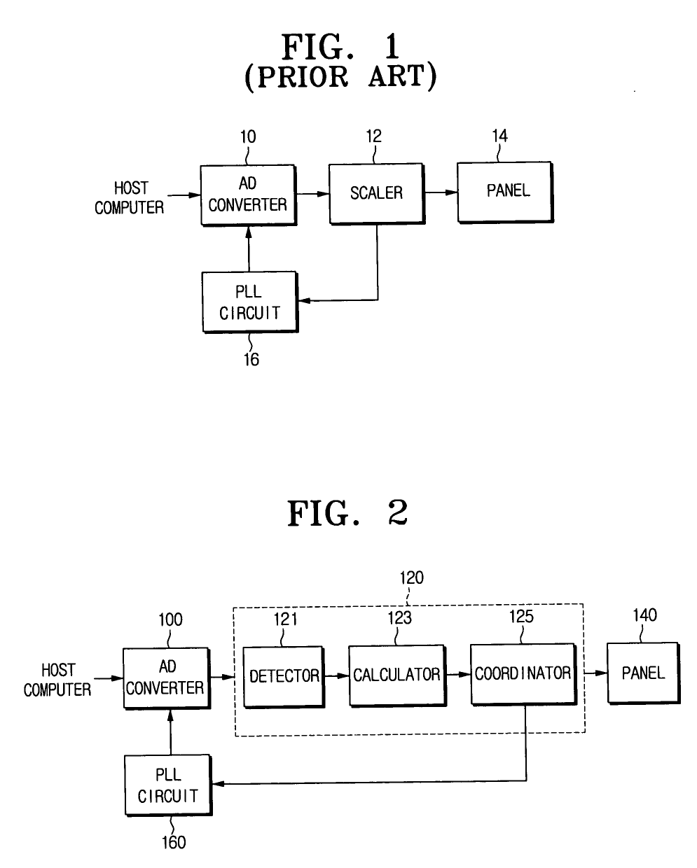

### DETAILED DESCRIPTION OF THE EXEMPLARY EMBODIMENTS

Certain exemplary embodiments of the present invention will be described in greater detail with reference to the accompanying drawings.

FIG. 2 is a block diagram showing a configuration of an image display apparatus according to an exemplary embodiment of the invention.

Referring to FIG. 2, the image display apparatus comprises an AD converter 100, a scaler 120, a display panel 140, and a PLL circuit 160.

The AD converter 100 samples analog image signals received from a host computer according to synchronization signals provided by the PLL circuit 160 described below, and converts the sampled signals into digital image data. Here, the PLL circuit 160 refers to a mode table supported by the image display apparatus, and provides synchronization signals to the AD converter 100. The AD converter 100 converts analog image signals received from the host computer into digital image data corresponding to the default mode according to the synchronization signals.

That is, in a case where the input image mode is XGA(1024*768) at 60 Hz, the Horizontal Total Width of 1344 and the Horizontal Active Width of 1024 are proposed as default values in the mode table stored in a storage device (not shown). Here, the Horizontal Total Width is the total number of pixels making up of the horizontal back porch region, horizontal front porch region, and Horizontal Active Width included in one horizontal line. The Horizontal Active Width is the number of pixels (i.e., horizontal resolution) displayed on a screen in one horizontal line. The AD converter 100 samples analog image signals, and converts the sampled signals into 1344 digital image data corresponding to the pixels included in the Horizontal Total Width and 1024 digital image data corresponding to the pixels included in the Horizontal Active Width.

The scaler 120 receives digital image data from the AD converter 100, and calculates horizontal and vertical positions. The scaler performs coarse and fine frequency tuning, and displays digital image data on a screen. In order to perform these operations, the scaler 120 includes a detector 121, a calculator 123, and a coordinator 125.

The detector 121 determines a threshold value, compares the threshold value with the pixel values included in a certain Capture Rectangle (CR) region and the pixel values included in the Horizontal Active Width, and detects the start point and the end point of the Horizontal Active Width. Here, a value obtained by experiment (approximately 8×Horizontal Active Width/2) is determined as the threshold value being used. The CR region is a portion of a blank region that is actually not displayed on a screen. That is, the CR region is included in the horizontal back porch region and horizontal front porch region, and portions of the horizontal back porch region and horizontal front porch region included in the CR region are the same in size. Here, if the border of the CR region and the Horizontal Active Width is clear, the start point and the end point detected by the detector 121 are the same value.

The detector 121 detects the start point and the end point using the difference between the pixel values of pixels included in each region. Here, starting from the first pixel of the CR region, the pixel value of a pixel is compared with the threshold value, and the start point is detected. Then, starting from the last pixel of the CR region, the pixel value of a pixel is compared with the threshold value, and the end point is detected. Here, the detector 121 judges the points having different pixel values as the start point and the end point. The reason is that the pixel values of the pixels included in the CR region are smaller than the threshold value, and the pixel values of the pixels included in the Horizontal Active Width are larger than the threshold value.

The calculator 123 calculates the Horizontal Active Width through the difference between two points, i.e., the start point and the end point. That is, if an accurate start point and end point are detected, the two points have the same value. Using the values of these two points, the Horizontal Active Width is calculated as follows in Equation 1:
Horizontal Active Width=default Horizontal Active Width+(start point−end point) [Equation 1]

For example, in a case where the input image mode is XGA(1024*768)@60 Hz, the default Horizontal Active Width is 1024. In a case where the AD converter 100 performs AD conversion normally, the default Horizontal Active Width is calculated as 1024, i.e., the default Horizontal Active Width. However, in a case where the AD converter 100 does not perform AD conversion normally, a difference occurs in the Horizontal Active Width.

In a case where a difference occurs between the calculated Horizontal Active Width and the default Horizontal Active Width, the coordinator 125 transfers compensation data to the PLL circuit 160 to compensate for the difference. For example, in a case where the input image mode is XGA(1024*768) at 60 Hz, if the Horizontal Active Width is calculated as 1025, the coordinator 125 transfers compensation data to the PLL circuit 160 so that the Horizontal Total Width becomes 1343, a value less than the default value of 1344. In this way, the Horizontal Active Width of 1024 is obtained.

However, due to this compensation, the Horizontal Total Width is forcibly changed. Here, the Horizontal Total Width is proved to be approximately in the range of 1343≦1344≦1346 by experimentation. In a case where the Horizontal Total Width is 1343, Equation 2 below is applied, and in a case where the Horizontal Total Width is in the range of 1345-1346, Equation 3 below is applied.
1343÷4=335.75→round (336)→336*4=1344 [Equation 2]
1345÷4=336.25→int operation (336)→336*4=1344
1346÷4=336.5→int operation (336)→336*4=1344 [Equation 3]

Through these separate operations, the coordinator 125 transfers accurate compensation data to the PLL circuit 160.

As explained above, the PLL circuit 160 creates compensated synchronization signals using compensation data and provides them to the AD converter 100, and the AD converter 100 converts analog image data into digital image data according to the compensated synchronization signals. Then, the scaler 120 scales the digital image data so as to correspond to the default mode.

The display panel 140 outputs the digital image data scaled at the scaler 120 on a screen. That is, in a case where the image signals received from a host computer are SVGA, the signals are displayed on a screen in the size of 600*800, 1024*768 in the case of XGA and 1280*1024 in the case of SXGA.

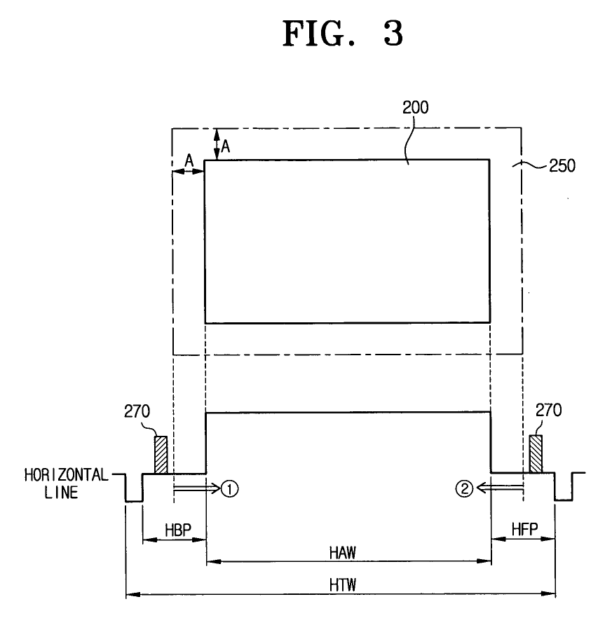

FIG. 3 explains the operation of the scaler of an image display apparatus according to an exemplary embodiment of the invention.

Referring to FIG. 3, in order to calculate the Horizontal Active Width (HAW), the scaler 120 creates a Capture Rectangle (CR) region 250 extending the HAW up, down, left, and right by the width A. This operation is initially performed in order to detect the start point and the end point at the detector 121 of the scaler 120. Here, the created CR region is included in the horizontal back porch (HBP) region and the horizontal front porch (HFP) region, which are in a horizontal line.

The detector 121 compares pixel values with the threshold value 270 in the direction \textcircled{1}, and detects the start point. Here, the pixel values included in the HBP region are smaller than a threshold value 270, and the pixel values included in the HAW region are larger than the threshold value 270, so that the detector 121 detects the first pixel where the larger value is detected as the start point.

In addition, in the same way, the detector 121 compares pixel values included in a horizontal line with the threshold value 270 in the direction \textcircled{2}, and detects the end point. Here, the pixel values included in the HFP region are smaller than the threshold value 270, and the pixel values included in the HAW region are larger than the threshold value 270, so that the first pixel where the larger value is detected is determined as the end point.

A horizontal total width (HTW) is the total number of pixels of the HBP region, HFP region, and HAW in one horizontal line.

In this way, the detected start point and end point are placed into the Equation I so that the HAW is calculated, and it is determined whether or not to compensate.

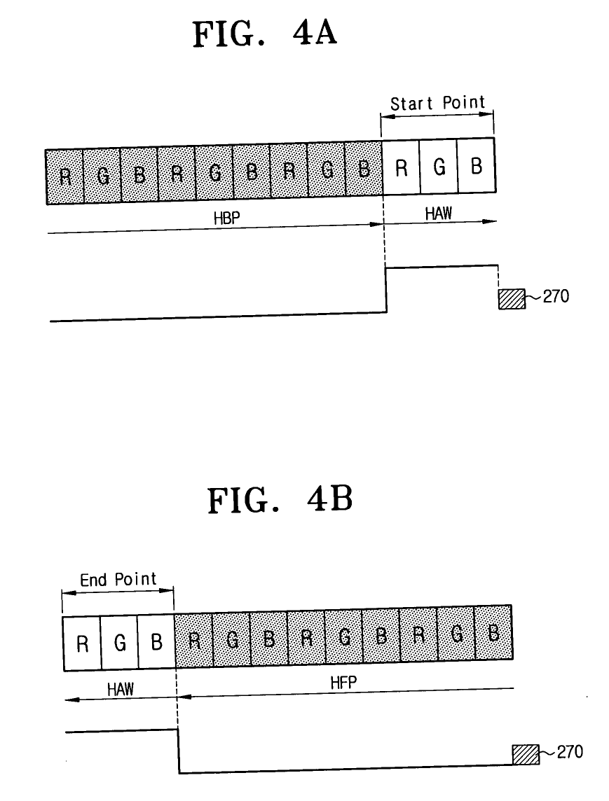

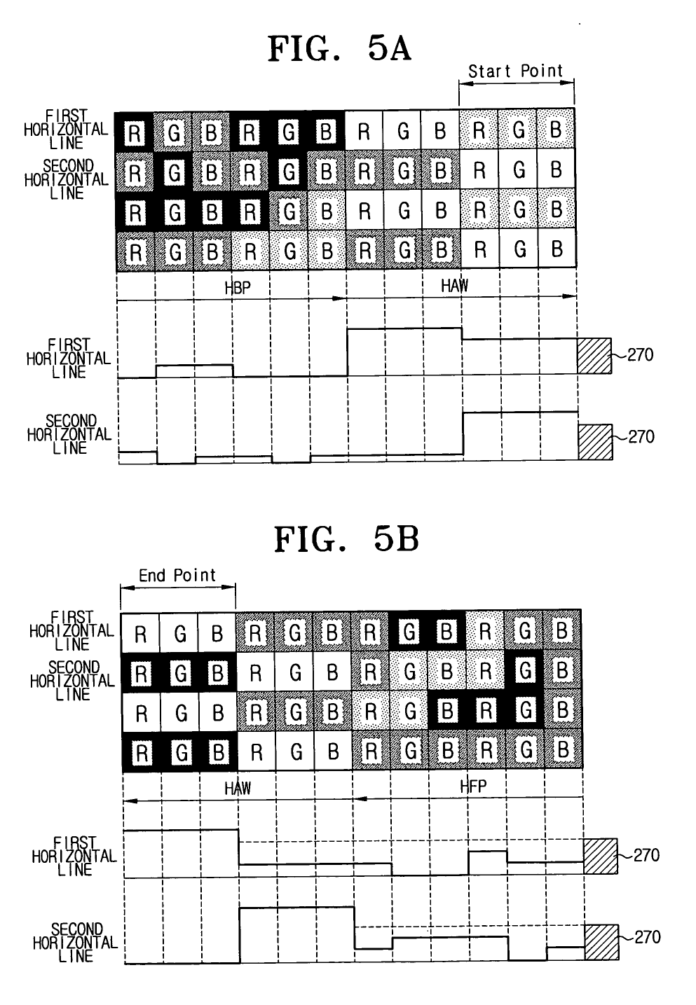

FIGS. 4A and 4B explain a method of detecting a start point and an end point from a crosshatch pattern for an image display apparatus according to an exemplary embodiment of the invention.

Here, the crosshatch pattern is a pattern that clearly divides the HAW that is displayed on a screen and the blank region that is not displayed on a screen.

Referring to FIG. 4A, the HBP region and the HAW are clearly divided in the crosshatch pattern, so that the start point can be detected in the same way as explained in FIG. 3. That is, pixel values are compared with the threshold value 270 in the direction from the HBP region to the HAW, the first pixel having a pixel value larger than the threshold value is the start point of the HAW.

Referring to FIG. 4B, the HAW and the HFP region are clearly divided in the crosshatch pattern, so that the end point can also be detected in the same way as explained in FIG. 3. That is, pixel values are compared with the threshold value 270 in the direction from the HFP region to the HAW, the first pixel having a pixel value larger than the threshold value 270 is the end point of the HAW.

If the PLL circuit 160 provides normal synchronization signals to the AD converter 100 and the AD converter performs AD conversion, in most cases, the start point and the end point will have the same value in the crosshatch pattern.

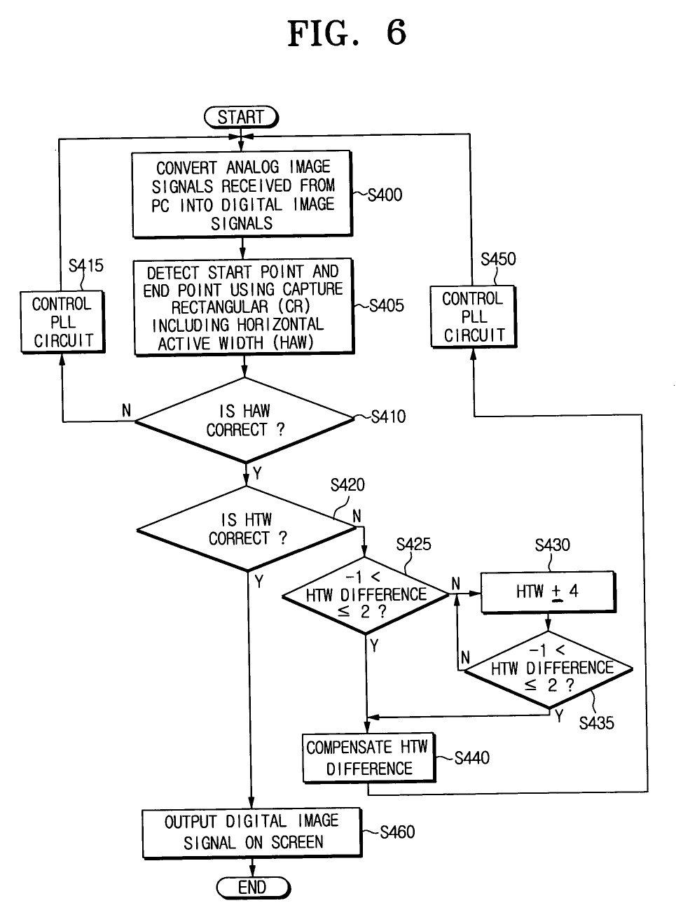

FIGS. 5A and 5B explain a method of detecting a start point and an end point from a “1 dot on/off” pattern for an image display apparatus according to an exemplary embodiment of the invention.

Here, the 1 dot on/off pattern is a pattern that does not clearly divide the HAW that is displayed on a screen and the blank region that is not displayed on a screen.

Referring to FIG. 5A, the HBP region and the HAW are not clearly divided in the 1 dot on/off pattern, so that if the start point is detected in the same way as explained in FIG. 3, a case may occur where the pixel that is shifted by one pixel is detected as the start point. The reason is that even though a normal start point is detected in the first horizontal line, a pixel shifted by one pixel is detected as the start point in the second horizontal line. Therefore, the detector 121 commits an error in detecting the start point.

Referring to FIG. 5B, if the start point is detected in the same way as explained in FIG. 3, a case may occur where the pixel that is shifted by one pixel is detected as the end point. The reason is that even though a normal end point is detected in the first horizontal line, a pixel shifted by one pixel is detected as the end point in the second horizontal line. Therefore, the detector 121 commits errors in detecting the end point.

As shown in the examples of FIGS. 5A and 5B, an accurate start point and end point are hard to detect in the 1 dot on/off pattern. That is, since the start point and the end point are detected incorrectly, a difference occurs in the size of the HAW. Therefore, in order to compensate for such a difference, the scaler 120 adjusts the value of the HTW and transfers the adjusted value to the PLL circuit 160. At this point, the scaler 120 performs operations so as not to deviate from the default value, and transfers the compensated data to the PLL circuit 160.

FIG. 6 is a flowchart explaining the operation of an image display apparatus according to an exemplary embodiment of the invention.

Referring to FIG. 6, analog image signals received from a host computer are converted into digital image data. That is, the analog image signals received from a host computer are sampled according to the synchronization signals provided by the PLL circuit 160 described below, and the sampled signals are converted into digital image data corresponding to the default mode (S400).

Then, using the Capture Rectangle (CR) region 250 that includes the HAW, the start point and the end point are detected. That is, the detector 121 determines a threshold value, compares the threshold value with the pixel values included in the CR region 250 and the pixel values included in the HAW, the CR region being a portion of a blank region that is not displayed on a screen, and detects the start point and the end point of the HAW (S405).

At this point, the calculator 123 calculates the HAW through the difference between two points, i.e., the start point and the end point (S410).

If the HAW is different from the default HAW, i.e., the start point and the end point are different from those of the default HAW, the calculator 125 adjusts the HTW, and transfers the compensation data to the PLL circuit (S415).

Here, in a case where the HTW is forcibly deviated from the default HTW (S420), if the difference is between −1 and 2 (S425), the calculator 123 compensates for the difference in the HTW using the mathematical formulas 2 and 3 (S440). Then, the coordinator 125 transfers the compensation data to the PLL circuit 160.

In a case where the HTW forcibly deviates from the default HTW, if the difference is outside the range of −1 to 2 (S425), the calculator 123 subtracts four from the HTW or adds four to the HTW (S430). Then, if the difference is still outside the range of −1 to 2 (S435), four is again added to the HTW. However, if the difference is in the range of −1 and 2, operations S440 and S450 are repeated.

In this way, the difference is compensated for, and digital image data is output on a screen (S460).

As described above, according to the invention, through an algorithm performing an automatic adjusting function, the image signals of an image mode of an old-style video card transmitted from a host computer or the image signals of an image mode that does not comply with Video Electronics Standards Association (VESA) specifications are output on a screen, so that clear images are implemented.

The foregoing embodiments and advantages are merely exemplary and are not to be construed as limiting the present invention. The present teachings can be readily applied to other types of apparatuses. Also, the description of the exemplary embodiments of the present invention is intended to be illustrative, and not to limit the scope of the claims, and many alternatives, modifications, and variations will be apparent to those skilled in the art.

What is claimed is:

1. An image display apparatus comprising:
an analog-to-digital (AD) converter which converts analog image signals into digital image data;
a phase-locked loop (PLL) circuit which provides the AD converter with synchronization signals utilized for converting the analog image signals into the digital image data; and
a scaler which calculates a Horizontal Active Width from the digital image data, compares the calculated Horizontal Active Width with a default Horizontal Active Width corresponding to a default mode, and transfers compensation data to the PLL circuit to compensate for a difference in the Horizontal Active Width.

2. The apparatus as claimed in claim 1, wherein the PLL circuit adjusts the synchronization signals according to the compensation data, and provides the adjusted synchronization signals to the AD converter.

3. The apparatus as claimed in claim 1, wherein the scaler comprises:
a detector which detects a start point and an end point of the Horizontal Active Width;
a calculator which calculates the Horizontal Active Width using the start point and the end point, compares the Horizontal Active Width with the default Horizontal Active Width, and creates compensation data for compensating the Horizontal Active Width based on the comparison; and
a coordinator which transfers the compensation data to the PLL circuit and controls the PLL circuit so as to compensate the synchronization signals.

4. The apparatus as claimed in claim 3, wherein the detector determines a Capture Rectangle (CR) region including a pixel section of a horizontal back porch region that is a blank region not included in the Horizontal Active Width, compares pixel values with a threshold value, the pixel values starting from a pixel value of a first pixel in the CR region, and detects a first pixel having a pixel value larger than the threshold value as the start point.

5. The apparatus as claimed in claim 4, wherein the detector determines a CR region including the certain pixel section of a horizontal front porch region that is a blank region not included in the Horizontal Active Width, compares pixel values with the threshold value, the pixel values starting from a pixel value of a last pixel in the CR region, and detects a first pixel having a pixel value larger than the threshold value as the end point.

6. The apparatus as claimed in claim 5, wherein the calculator calculates the Horizontal Active Width to be equal to the default Horizontal Active Width plus the start point minus the end point.

7. The apparatus as claimed in claim 3, wherein the calculator calculates compensation data for compensating a Horizontal Total Width, which comprises the Horizontal Active Width and a blank region, so as to have a same value as a default Horizontal Total Width that corresponds to the default mode, the blank region not being included in the Horizontal Active Width and comprising a horizontal back porch region and a horizontal front porch region.

8. An automatic adjusting method for an image display apparatus, the method comprising:
converting analog image signals into digital image data according to synchronization signals;
calculating a Horizontal Active Width from the digital image data; and
generating compensation data for compensating for a difference in the Horizontal Active Width based on a comparison of the Horizontal Active Width with a default Horizontal Active Width corresponding to a default mode.

9. The method as claimed in claim 8, further comprising the steps of:
adjusting the synchronization signals according to the compensation data;
converting the analog image signals into the digital image data according to the compensated synchronization signals; and
displaying the digital image data on a screen after scaling.

10. The method as claimed in claim 8, wherein the calculating the Horizontal Active Width comprises calculating a size of the Horizontal Active Width to be equal to the default Horizontal Active Width plus a start point minus an end point, whereby, when a threshold value is compared with pixel values starting from a first pixel value in a Capture Rectangle (CR) region including a pixel section of a Horizontal Back Porch region, the start point is a first pixel having a larger pixel value than the threshold value, and, when a certain threshold value is compared with pixel values starting from a last pixel value in a CR region including a certain pixel section of a Horizontal Front Porch region, the end point is a first pixel having a larger pixel value than the threshold value.

11. The method as claimed in claim 8, wherein the generating the compensation data comprises calculating compensation data for compensating a Horizontal Total Width, which comprises the Horizontal Active Width and a blank region, so as to have a same value as a default Horizontal Total Width that corresponds to the default mode, the blank region not being included in the Horizontal Active Width and comprising a horizontal back porch region and a horizontal front porch region.
